(19) United States
(12) Patent Application Publication
(10) Pub. No.: US 2026/0344163 A1
(43) Pub. Date: Oct. 29, 2026

(54) LED DISPLAY DEVICE

(71) Applicant: STAR ASIA VISION CORPORATION, Hsinchu City (TW)

(72) Inventors: Yu-Hung Hsiao, Hsinchu City (TW); Kuo-Shu Huang, Hsinchu City (TW); Kao-Nan Chen, Hsinchu City (TW)

(21) Appl. No.: 19/660,420

(22) Filed: Apr. 28, 2026

(30) Foreign Application Priority Data
Apr. 28, 2025 (TW) 114115885

(51) Int. Cl. H10H 29/855; H10H 29/852

(52) U.S. Cl. CPC H10H 29/8552; H10H 29/852

(57) ABSTRACT

An LED display device which includes a substrate and a plurality of light emitting units. Each light emitting unit has an LED element and a cover plate both disposed on the substrate. The cover plate includes a light shield, a hollow portion, a first side, and a second side opposite to the first side. The light shield is disposed on a surface of the first side and surrounds the LED element. The hollow portion penetrates the light shield so that the LED element emits light through the hollow portion. The light shield includes a horizontal side wall and a notch located on the horizontal side wall. The horizontal side wall deviates from a light emitting center of the LED element along a negative Y-axis direction, and based on a direction parallel to a Z-axis direction, a height of the notch is smaller than a height of the horizontal sidewall to increase a vertical downward viewing angle of the LED element.

### CROSS-REFERENCE TO RELATED APPLICATIONS

This application claims the benefit of priority to Taiwanese Patent Application No. 114115885 filed on Apr. 28, 2025, which is hereby incorporated by reference in its entirety.

### BACKGROUND OF THE INVENTION

### Field of the Invention

The present invention relates to an LED display device, and more particularly to an LED display device that controls viewing angle ranges to reduce light pollution.

### Brief Description of the Related Art

Generally, LED display devices installed outdoors are mostly used as advertising billboards. A larger light emitting angle of an LED element allows more people to view with the naked eye within a line of sight, thereby creating maximum advertising effectiveness.

However, with the increasing demand for advertising, the aforementioned LED display devices are widely installed, leading to increasingly serious light overflow and diffusion, which causes the aforementioned LED display devices to become sources of light pollution in nighttime environments. Currently, to improve this phenomenon, some manufacturers add shielding objects to the housing of the aforementioned LED display device or the surrounding environment to block light; however, the aforementioned practice increases the costs associated with installation expenses and labor hours.

Therefore, how to design an LED display device that can improve the aforementioned problems is indeed a subject worthy of research.

### SUMMARY OF THE INVENTION

An object of the present invention is to provide an LED display device that controls a viewing angle range to reduce light pollution.

To achieve the above object, the present invention discloses an LED display device comprising a substrate and a plurality of light emitting units. The substrate is located on an XY plane, and the XY plane is perpendicular to a Z-axis direction. Each of the light emitting units includes an LED element and a cover plate. The LED element is disposed on the substrate and defines a light emitting center. The cover plate is disposed on the substrate and includes a light shield, a hollow portion, a first side, and a second side opposite to the first side. The light shield is disposed on a surface of the first side and surrounds the LED element. The hollow portion penetrates the light shield so that the LED element emits light through the hollow portion. Wherein, the light shield includes a horizontal side wall and a notch located on the horizontal side wall. The horizontal side wall deviates from the light emitting center along a negative Y-axis direction, and based on a direction parallel to the Z-axis direction, a height of the notch is smaller than a height of the horizontal side wall to increase a vertical downward viewing angle of the LED element.

In one embodiment of the present invention, the LED element defines the vertical downward viewing angle between a light emitting center axis passing through the light emitting center and the notch of the light shield, and the vertical downward viewing angle is greater than 0 degrees and not greater than 40 degrees.

In one embodiment of the present invention, the cover plate further includes a first horizontal light shielding plate, the first horizontal light shielding plate is disposed on a surface of the first side and connected to the light shield, and based on a direction parallel to the Z-axis direction, a height of the first horizontal light shielding plate is greater than a height of the light shield to limit a vertical upward viewing angle of the LED element.

In one embodiment of the present invention, the LED element defines the vertical upward viewing angle between the light emitting center axis passing through the light emitting center and the first horizontal light shielding plate, and the vertical upward viewing angle is greater than 0 degrees and not greater than 25 degrees.

In one embodiment of the present invention, the light shield further includes two vertical side walls, each of the vertical side walls has two ends respectively connected to the horizontal side wall and the first horizontal light shielding plate, the LED element defines a horizontal viewing angle between the light emitting center axis and the two vertical side walls, and the horizontal viewing angle is between 25 degrees and 90 degrees.

In one embodiment of the present invention, the light shield is a truncated quadrangular pyramid that tapers in a direction away from the LED element, and an inclination angle of each lateral surface of the truncated quadrangular pyramid is between 1 and 10 degrees.

In one embodiment of the present invention, the hollow portion forms a first opening at the first side and a second opening at the second side, and a cross-sectional area of the first opening is smaller than a cross-sectional area of the second opening.

In one embodiment of the present invention, the hollow portion forms a truncated quadrangular pyramid-shaped space that tapers from the second opening toward the first opening, and an inclination angle of each lateral surface of the truncated quadrangular pyramid-shaped space is between 1 and 10 degrees.

In one embodiment of the present invention, the hollow portion defines a hollow center, and a position of the light emitting center deviates from the hollow center along a positive Y-axis direction.

In one embodiment of the present invention, the cover plate further includes at least one second horizontal light shielding plate, each of the at least one second horizontal light shielding plate is disposed on the surface of the first side and located between the horizontal side wall of the light shield and a lower edge of the cover plate.

In one embodiment of the present invention, the cover plate further includes a plurality of reflective structures, and the plurality of reflective structures are disposed on the surface of the first side other than where the first horizontal light shielding plate and the light shield are disposed.

In one embodiment of the present invention, the cover plate of each of the light emitting units is connected to the cover plate of another adjacent one of the light emitting units.

After referring to the drawings and the embodiments as described in the following, those having ordinary skill in the art can understand other objectives of the present invention, as well as the technical means and embodiments of the present invention.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a partial perspective schematic view of the LED display device of the present invention;

FIG. 2 is a partial perspective exploded view of the LED display device of the present invention;

FIG. 3 is a partially enlarged perspective schematic view of the LED display device of the present invention;

FIG. 4 is a partially enlarged front view of the LED display device of the present invention;

FIG. 5 is a partial cross-sectional view taken along line A-A in FIG. 4;

FIG. 6 is a partial cross-sectional view taken along line B-B in FIG. 4;

FIG. 7 is a schematic view of the LED display device of the present invention applied to an outdoor environment;

FIG. 8 is a schematic view of the light intensity ratio between the LED display device of the present invention and a conventional LED display device applied to an outdoor environment; and

FIG. 9 is a schematic view of the luminance and angle between the LED display device of the present invention and a conventional LED display device applied to an outdoor environment.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application, or particular method for implementations described in these embodiments. Therefore, the description of these embodiments is for illustrative purposes only and is not intended to limit the present invention. In the following embodiments and drawings, components not directly related to the present invention are omitted, and the dimensional relationships among the elements in the drawings are shown for ease of understanding and are not intended to limit actual proportions.

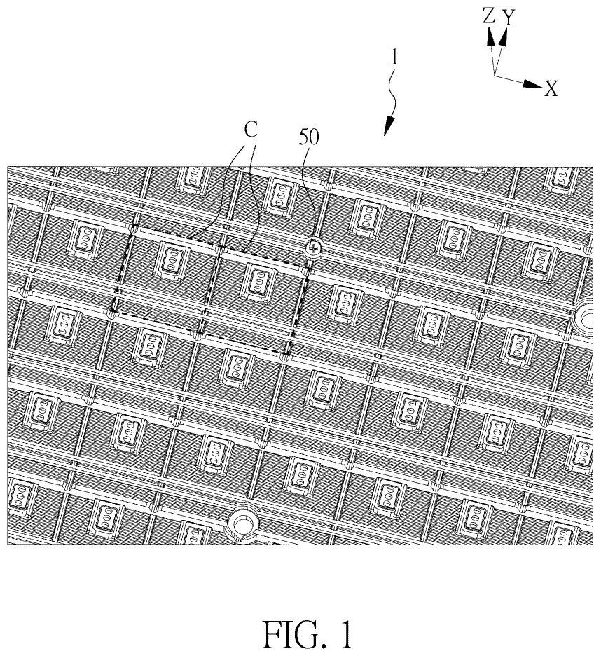

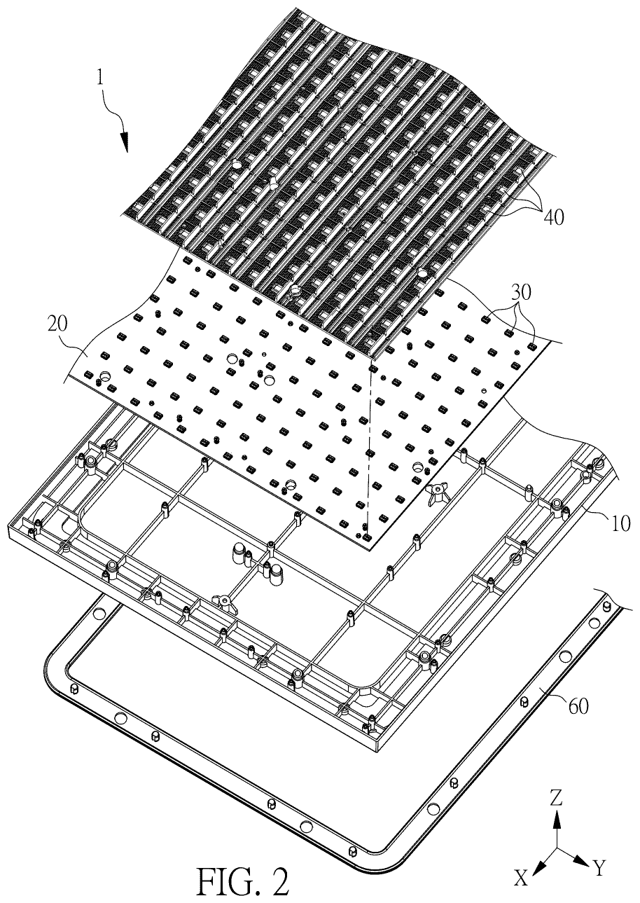

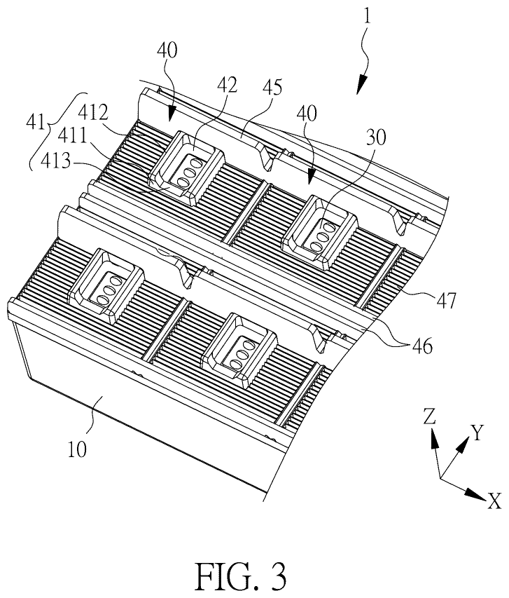

Please refer to FIG. 1 to FIG. 3 together, wherein FIG. 1 is a partial perspective schematic view of the LED display device 1 of the present invention, FIG. 2 is a partial perspective exploded view of the LED display device 1 of the present invention, and FIG. 3 is a partially enlarged perspective schematic view of the LED display device 1 of the present invention. As shown in FIG. 1 to FIG. 3, the LED display device 1 of the present invention comprises a housing 10, a substrate 20, and a plurality of light emitting units C. The substrate 20 is disposed on the housing 10, and the plurality of light emitting units C are disposed on the substrate 20 in a matrix arrangement. The substrate 20 is a printed circuit board. In the following description of the embodiments of the present invention, the substrate 20 is located on an XY plane perpendicular to the ground (i.e., a plane constituted by an X-axis direction and a Y-axis direction perpendicular to each other), and the XY plane is perpendicular to a Z-axis direction, such that the LED display device 1 of the present invention as a whole mainly uses the XY plane as a display surface, but the present invention is not limited to the aforementioned defined axial directions. For ease of understanding, labels for the X-axis direction, the Y-axis direction, and the Z-axis direction are attached to the drawings of the present invention.

Each of the light emitting units C includes an LED element 30 and a cover plate 40. The LED element 30 is directly disposed on the substrate 20 and electrically connected to corresponding driving circuits (not shown) and a power source (not shown) to emit light through signal driving. In the present invention, the LED element 30 is a surface mount device (SMD) type LED element or a lamp type LED element, but other types of LED elements may also be adopted. The cover plate 40 is disposed on the substrate 20. In one embodiment of the present invention, the cover plate 40 of each of the light emitting units C is connected to the cover plate 40 of another adjacent one of the light emitting units C, such that the cover plates 40 of the light emitting units C are combined into a large cover body, to facilitate locking the cover plates 40, the substrate 20, and the housing 10 together by a locking element 50 (such as a screw, a rivet, or an element having a similar locking function). In addition, the LED display device 1 of the present invention further comprises a waterproof gasket 60 combined with an opposite side of the housing 10 where the substrate 20 is disposed, to provide a waterproof function.

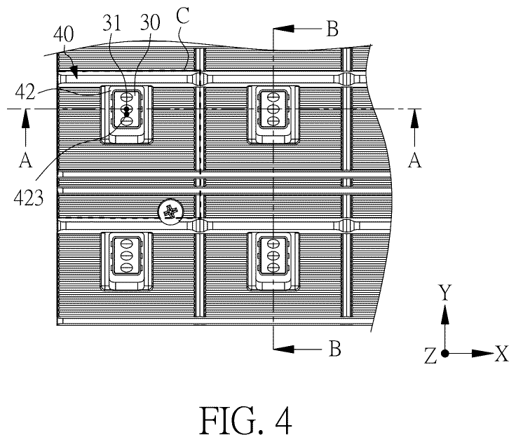

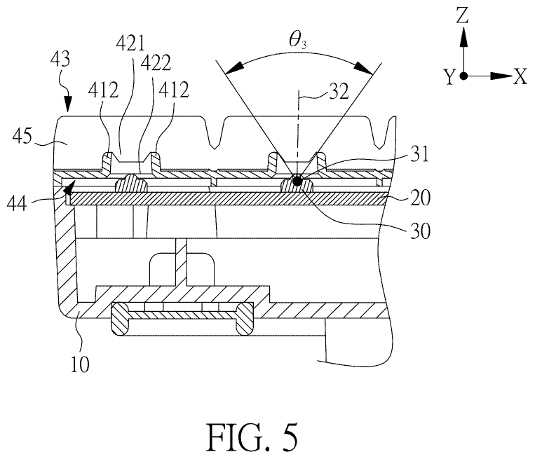

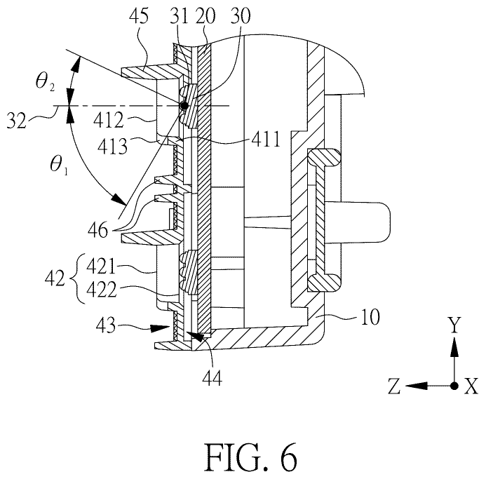

Please refer to FIG. 3 to FIG. 6 together, wherein FIG. 4 is a partially enlarged front view of the LED display device 1 of the present invention, FIG. 5 is a partial cross-sectional view taken along line A-A in FIG. 4, and FIG. 6 is a partial cross-sectional view taken along line B-B in FIG. 4. As shown in FIG. 3 to FIG. 6, the LED element 30 of each of the light emitting units C defines a light emitting center 31, and an axis passing through the light emitting center 31 and parallel to the Z-axis direction is defined as a light emitting center axis 32. The cover plate 40 of each of the light emitting units C includes a light shield 41, a hollow portion 42, and a first side 43 and a second side 44 opposite to the first side 43. The light shield 41 is disposed on a surface of the first side 43 and surrounds the LED element 30. Based on the direction parallel to the Z-axis direction, a height of the light shield 41 is greater than a height of the LED element 30, such that a viewing angle range of the LED element 30 can be limited by the light shield 41.

In one embodiment of the present invention, the light shield 41 includes a horizontal side wall 411, two vertical side walls 412, and a notch 413. A length of the horizontal side wall 411 extends along the X-axis direction, and a disposal position of the horizontal side wall 411 deviates from the light emitting center 31 (i.e., using the light emitting center 31 as an origin) along a negative Y-axis direction. Two ends of the horizontal side wall 411 are respectively connected to different vertical side walls 412 to constitute a frame. A length of each of the vertical side walls 412 extends along the Y-axis direction, and disposal positions of the two vertical side walls 412 deviate from the light emitting center 31 (i.e., using the light emitting center 31 as an origin) along a positive X-axis direction and a negative X-axis direction, respectively, such that the two vertical side walls 412 are oppositely disposed based on the light emitting center 31. The notch 413 is located on the horizontal side wall 411, and based on the direction parallel to the Z-axis direction, a height of the notch 413 is smaller than a height of the horizontal side wall 411 and a height of the vertical side walls 412. Furthermore, based on the direction parallel to the Z-axis direction, the heights of the horizontal side wall 411, the vertical side walls 412, and the notch 413 are all greater than the height of the LED element 30. In one embodiment of the present invention, based on the direction parallel to the Z-axis direction, the light shield 41 forms a truncated quadrangular pyramid that tapers in a direction away from the LED element 30, and an inclination angle of each lateral surface of the truncated quadrangular pyramid is between 1 and 10 degrees.

The hollow portion 42 penetrates the light shield 41 from the first side 43 of the cover plate 40 to the second side 44, and a disposal position of the LED element 30 corresponds to a disposal position of the hollow portion 42, such that the LED element 30 emits light through the hollow portion 42. The hollow portion 42 forms a first opening 421 at the first side 43 and a second opening 422 at the second side 44, and a cross-sectional area of the first opening 421 is smaller than a cross-sectional area of the second opening 422. In one embodiment of the present invention, based on the direction parallel to the Z-axis direction, the hollow portion 42 forms a truncated quadrangular pyramid-shaped space that tapers from the second opening 422 toward the first opening 421, and an inclination angle of each lateral surface of the truncated quadrangular pyramid-shaped space is between 1 and 10 degrees. Based on the direction parallel to the Z-axis direction, a height of the first opening 421 is greater than the height of the LED element 30.

Accordingly, the LED element 30 of each of the light emitting units C defines a vertical downward viewing angle θ₁ between the light emitting center axis 32 passing through the light emitting center 31 and the notch 413 of the light shield 41, and the vertical downward viewing angle θ₁ of the LED element 30 is increased by the height design of the notch 413. In one embodiment of the present invention, the vertical downward viewing angle θ₁ is greater than 0 degrees and not greater than 40 degrees, but the present invention is not limited thereto.

In one embodiment of the present invention, the cover plate 40 further includes a first horizontal light shielding plate 45. The first horizontal light shielding plate 45 can provide an effect of blocking external light (such as sunlight) from interfering with the light mixing of the LED element 30. The first horizontal light shielding plate 45 is disposed on the surface of the first side 43 and connected to the light shield 41. A length of the first horizontal light shielding plate 45 extends along the X-axis direction, and a disposal position of the first horizontal light shielding plate 45 deviates from the light emitting center 31 (i.e., using the light emitting center 31 as an origin) along a positive Y-axis direction, such that the first horizontal light shielding plate 45 and the horizontal side wall 411 of the light shield 41 are oppositely disposed based on the light emitting center 31. Two ends of each of the vertical side walls 412 are respectively connected to the horizontal side wall 411 and the first horizontal light shielding plate 45. Based on the direction parallel to the Z-axis direction, a height of the first horizontal light shielding plate 45 is greater than a height of the light shield 41 (including the horizontal side wall 411, the vertical side walls 412, and the notch 413), and the height of the first horizontal light shielding plate 45 is greater than the height of the LED element 30. Accordingly, when external light illuminates the cover plate 40, a shadow is generated below the first horizontal light shielding plate 45 to shield the LED element 30, thereby avoiding interference caused by external light to the LED element 30.

In the present invention, the LED element 30 of each of the light emitting units C defines a vertical upward viewing angle θ₂ between the light emitting center axis 32 passing through the light emitting center 31 and the first horizontal light shielding plate 45, and the vertical upward viewing angle θ₂ of the LED element 30 is limited by the height design of the first horizontal light shielding plate 45. In one embodiment of the present invention, the vertical upward viewing angle θ₂ is greater than 0 degrees and not greater than 25 degrees, but the present invention is not limited thereto.

In conjunction with the design of the aforementioned first horizontal light shielding plate 45, in one embodiment of the present invention, the hollow portion 42 defines a hollow center 423, and a position of the light emitting center 31 of the LED element 30 deviates from the hollow center 423 (i.e., using the hollow center 423 as an origin) along a positive Y-axis direction. That is to say, the LED element 30 is closer to the first horizontal light shielding plate 45 and farther away from the notch 413 of the light shield 41. Accordingly, the vertical downward viewing angle θ₁ defined by the LED element 30 of each of the light emitting units C is further increased, and the vertical upward viewing angle θ₂ defined by the LED element 30 of each of the light emitting units C is further limited.

In addition, the LED element 30 of each of the light emitting units C defines a horizontal viewing angle θ₃ between the light emitting center axis 32 and the vertical side walls 412, and the horizontal viewing angle θ₃ of the LED element 30 is limited by the height design of the vertical side walls 412. In one embodiment of the present invention, the horizontal viewing angle θ₃ is between 25 degrees and 90 degrees, but the present invention is not limited thereto.

Through the design of the cover plate 40 of each light emitting unit C, the LED display device 1 of the present invention controls the viewing angle ranges of the LED element 30, including the vertical downward viewing angle θ₁, the vertical upward viewing angle θ₂, and the horizontal viewing angle θ₃, to avoid the light emitted from the LED element 30 from diverging toward excessively wide angles and causing environmental light pollution. At the same time, through the design of the notch 413 of the light shield 41, the LED display device 1 of the present invention can still maintain a certain degree of visible range while restricting the vertical downward viewing angle θ₁.

In addition, in one embodiment of the present invention, the cover plate 40 further includes at least one second horizontal light shielding plate 46. Each of the at least one second horizontal light shielding plate 46 is disposed on the surface of the first side 43, and each of the at least one second horizontal light shielding plate 46 is located between the horizontal side wall 411 of the light shield 41 and a lower edge of the cover plate 40. A disposal position of the second horizontal light shielding plate 46 deviates from the light emitting center 31 (i.e., using the light emitting center 31 as an origin) along a negative Y-axis direction and is closer to the lower edge of the cover plate 40. Based on the direction parallel to the Z-axis direction, a height of the second horizontal light shielding plate 46 is greater than the height of the light shield 41 (including the horizontal side wall 411, the vertical side walls 412, and the notch 413). The second horizontal light shielding plate 46 of the cover plate 40 of each light emitting unit C is connected to the second horizontal light shielding plate 46 of the cover plate 40 of another adjacent one of the light emitting units C on the left/right side. Accordingly, when external light illuminates the cover plate 40, a shadow is generated below the second horizontal light shielding plate 46, thereby shielding an assembly seam between the cover plate 40 of the light emitting unit C and the cover plate 40 of another adjacent one of the light emitting units C below, or forming a visual effect of uniform shadow line segments.

In addition, in one embodiment of the present invention, the cover plate 40 further includes a plurality of reflective structures 47. The plurality of reflective structures 47 are disposed on the surface of the first side 43 other than where the light shield 41 and the first horizontal light shielding plate 45 (and the second horizontal light shielding plate 46) are disposed. Through the disposal of the plurality of reflective structures 47, a reflection effect caused by external light directly hitting the surface of the cover plate 40 can be avoided, thereby preventing interference with the LED element 30.

In one embodiment of the present invention, the cover plate 40 may be made of the same material in an integrally formed manner. However, the present invention is not limited thereto. Different structural portions of the cover plate 40 (such as the light shield 41, the first horizontal light shielding plate 45, the second horizontal light shielding plate 46, etc.) may also be formed separately using the same or different materials and then combined with each other.

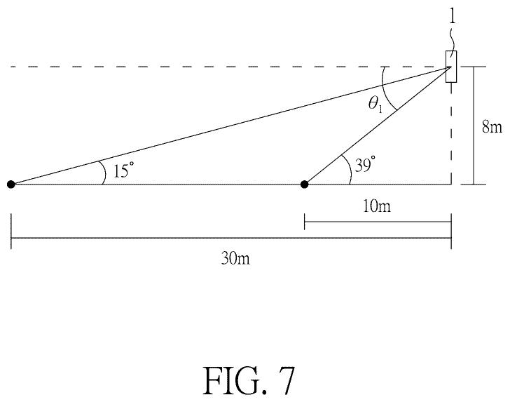

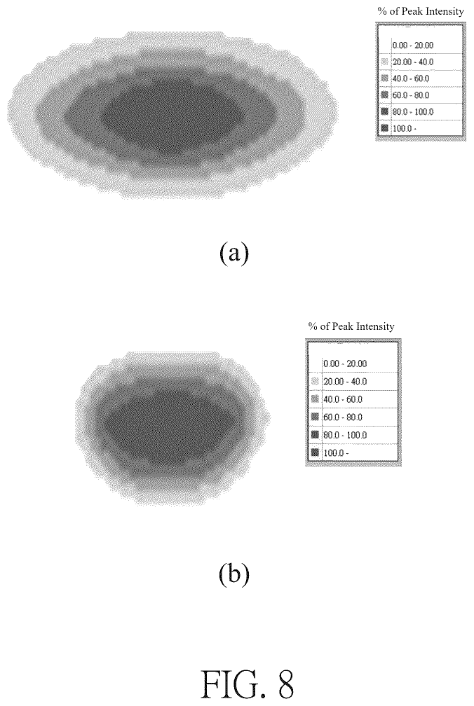

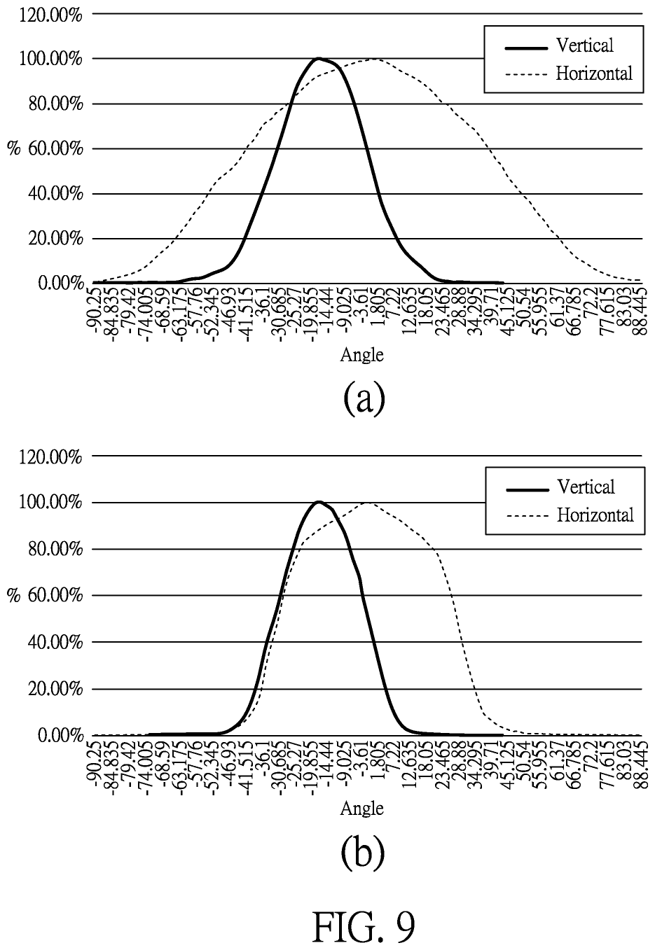

Please refer to FIG. 7 to FIG. 9, wherein FIG. 7 is a schematic view of the LED display device 1 of the present invention applied to an outdoor environment, FIG. 8 is a schematic view of the light intensity ratio between the LED display device of the present invention and a conventional LED display device applied to an outdoor environment, and FIG. 9 is a schematic view of the luminance and angle between the LED display device of the present invention and a conventional LED display device applied to an outdoor environment. As shown in FIG. 7, when the LED display device 1 of the present invention is used as an outdoor advertising billboard, the disposal position of the LED display device 1 of the present invention is usually set beside a general road or a highway, and it is at a certain height from the ground and has a large area, such that a viewer needs to view the LED display device 1 of the present invention at an elevation angle. The elevation angle is related to the vertical downward viewing angle θ₁ of the LED display device 1 of the present invention and a horizontal distance between the viewer and the LED display device 1 of the present invention.

For example, in one embodiment of the present invention, the LED display device 1 of the present invention is disposed at a height of about 7 to 9 meters from the ground (the center of the device is about 8 to 9 meters from the ground). Under this design, the viewer can view the LED display device 1 of the present invention from a distance using a small elevation angle. When the horizontal distance between the viewer and the LED display device 1 of the present invention is about 30 meters, the required elevation angle for the viewer to view the LED display device 1 of the present invention is about 15 degrees. When the horizontal distance between the viewer and the LED display device 1 of the present invention is about 10 meters, the required elevation angle for the viewer to view the LED display device 1 of the present invention is about 39 degrees, which is approximately equal to the upper limit of 40 degrees for the vertical downward viewing angle θ₁ of the LED display device 1 of the present invention. Once the horizontal distance between the viewer and the LED display device 1 of the present invention is less than 10 meters, even if the viewer uses a larger elevation angle, they still cannot smoothly view the LED display device 1 of the present invention. In other words, the light emitting effect of the LED display device 1 of the present invention does not affect the area within a horizontal distance of 10 meters in front. In conjunction with the limitation of viewing angles, such as the vertical upward viewing angle θ₂ and the horizontal viewing angle θ₃, the light pollution impact of the LED display device 1 of the present invention on the surrounding areas is further reduced.

Based on the installation method of the LED display device shown in FIG. 7, a comparative description of the light emitting effects between the LED display device 1 of the present invention and a conventional LED display device is provided below. The aforementioned conventional LED display device adopts, as a comparative example, a structural configuration obtained by removing the light-shielding cover 41 of the cover plate 40 from the LED display device 1 of the present invention, as shown in FIG. 3. As shown in FIG. 8, according to actual measurement data, the light intensity ratio of the conventional LED display device (as shown in part (a) of FIG. 8) has a wider range of divergence from the center outward, resulting in a larger area affected by light emission. In contrast, the light intensity ratio of the LED display device 1 of the present invention (as shown in part (b) of FIG. 8) has a more concentrated range of divergence from the center outward, thereby effectively reducing the area affected by light emission. Furthermore, as shown in FIG. 9, the horizontal and vertical light emitting angles of the conventional LED display device (as shown in part (a) of FIG. 9) are larger, resulting in a larger area affected by light emission. In contrast, the horizontal and vertical light emitting angles of the LED display device 1 of the present invention (as shown in part (b) of FIG. 9) are significantly smaller, thereby effectively reducing the area affected by light emission.

Accordingly, based on the aforementioned structural design, the LED display device 1 of the present invention limits the viewing angle to a relatively narrow range so as to prevent excessive divergence of high-intensity light, and allows viewers to observe the display device under specific conditions such as a certain distance and elevation angle. As such, the LED display device 1 of the present invention avoids generating excessive ineffective light that may easily cause light pollution in surrounding areas under dark environments. In addition, the LED display device 1 of the present invention is capable of limiting light exceeding the standard within a specific visual range, providing highly directional display image presentation. The LED display device 1 of the present invention not only ensures the visibility and attractiveness of the display content but also significantly reduces light pollution, enhancing the comfort and safety of the surrounding areas.

The above-described embodiments are essentially for illustrative purposes only and are not intended to limit the embodiments of the claimed subject matter or their applications or uses. Moreover, although at least one exemplary embodiment has been presented in the foregoing description, it should be understood that numerous modifications may still be made to the present invention. It should likewise be understood that the embodiments described herein are not intended to limit the scope, use, or configuration of the claimed subject matter in any way. On the contrary, the foregoing embodiments provide a convenient guide for those of ordinary skill in the art to implement one or more embodiments described herein. Furthermore, various modifications in function and arrangement of components may be made without departing from the scope defined by the appended claims, which encompass known equivalents as well as all foreseeable equivalents at the time of filing this patent application.

What is claimed is:

1. An LED display device, comprising:
a substrate, located on an XY plane, wherein the XY plane is perpendicular to a Z-axis direction; and
a plurality of light emitting units, each of the light emitting units including:
an LED element, disposed on the substrate, the LED element defining a light emitting center; and
a cover plate, disposed on the substrate, the cover plate having a light shield, a hollow portion, a first side, and a second side opposite to the first side, the light shield being disposed on a surface of the first side and surrounding the LED element, the hollow portion penetrating the light shield so that the LED element emits light through the hollow potion, wherein the light shield includes a horizontal side wall and a notch located on the horizontal side wall, the horizontal side wall deviates from the light emitting center of the LED element along a negative Y-axis direction, and based on a direction parallel to the Z-axis direction, a height of the notch is smaller than a height of the horizontal side wall to increase a vertical downward viewing angle of the LED element.

2. The LED display device according to claim 1, wherein the LED element defines the vertical downward viewing angle between a light emitting center axis passing through the light emitting center and the notch of the light shield, and the vertical downward viewing angle is greater than 0 degrees and not greater than 40 degrees.

3. The LED display device according to claim 2, wherein the cover plate further includes a first horizontal light shielding plate, the first horizontal light shielding plate is disposed on a surface of the first side and connected to the light shield, and based on the direction parallel to the Z-axis direction, a height of the first horizontal light shielding plate is greater than a height of the light shield to limit a vertical upward viewing angle of the LED element.

4. The LED display device according to claim 3, wherein the LED element defines the vertical upward viewing angle between the light emitting center axis passing through the light emitting center and the first horizontal light shielding plate, and the vertical upward viewing angle is greater than 0 degrees and not greater than 25 degrees.

5. The LED display device according to claim 3, wherein the light shield further includes two vertical side walls, each of the vertical side walls has two ends respectively connected to the horizontal side wall and the first horizontal light shielding plate, the LED element defines a horizontal viewing angle between the light emitting center axis and the two vertical side walls, and the horizontal viewing angle is between 25 degrees and 90 degrees.

6. The LED display device according to claim 3, wherein the light shield is a truncated quadrangular pyramid that tapers in a direction away from the LED element, and an inclination angle of each lateral surface of the truncated quadrangular pyramid is between 1 and 10 degrees.

7. The LED display device according to claim 1, wherein the hollow portion forms a first opening at the first side and a second opening at the second side, and a cross-sectional area of the first opening is smaller than a cross-sectional area of the second opening.

8. The LED display device according to claim 7, wherein the hollow portion forms a truncated quadrangular pyramid-shaped space that tapers from the second opening toward the first opening, and an inclination angle of each lateral surface of the truncated quadrangular pyramid-shaped space is between 1 and 10 degrees.

9. The LED display device according to claim 1, wherein the hollow portion defines a hollow center, and a position of the light emitting center deviates from the hollow center along a positive Y-axis direction.

10. The LED display device according to claim 3, wherein the cover plate further includes at least one second horizontal light shielding plate, each of the at least one second horizontal light shielding plate is disposed on the surface of the first side and located between the horizontal side wall of the light shield and a lower edge of the cover plate.

11. The LED display device according to claim 3, wherein the cover plate further includes a plurality of reflective structures, and the plurality of reflective structures are disposed on the surface of the first side other than where the first horizontal light shielding plate and the light shield are disposed.

12. The LED display device according to claim 1, wherein the cover plate of each of the light emitting units is connected to the cover plate of another adjacent one of the light emitting units.
